(19) United States
(12) Patent Application Publication
(10) Pub. No.: US 2019/0136159 A1
(43) Pub. Date: May 9, 2019

(54) BUTYLPYRROLIDONE BASED CLEANING AGENT FOR REMOVAL OF CONTAMINATES FROM ELECTRONIC AND SEMICONDUCTOR DEVICES

(71) Applicant: Kyzen Corporation, Nashville, TN (US)

(72) Inventors: Kyle J Doyel, Franklin, TN (US); Michael L Bixenman, Old Hickory, TN (US); Kevin Soucy, Nashville, TN (US); Haley Jones, Gallatin, TN (US)

(73) Assignee: Kyzen Corporation, Nashville, TN (US)

(21) Appl. No.: 16/132,082

(22) Filed: Sep. 14, 2018

Related U.S. Application Data
(60) Provisional application No. 62/576,436, filed on Oct. 24, 2017.

(51) Int. Cl. C11D 7/50; C11D 3/30; C11D 3/00; H01L 21/02; H05K 3/26; B08B 3/10

(52) U.S. Cl. CPC C11D 7/5013; C11D 7/5022; C11D 3/30; C11D 3/0073; H05K 2203/0776; H05K 3/26; B08B 3/10; H05K 2203/0783; H01L 21/02057

(57) ABSTRACT

A composition effective for removing contaminates from an electronic device either as a concentrated material or when diluted with water. The composition designed for effective removal of undesirable contaminates from an electronic device, including but not limited to, solder flux and polymeric residues. The composition contains butylpyrrolidone and an alkali and has a pH of greater than 7.1 and a pKa less than 12. The composition may contain additional optional solvents and additives to enhance cleaning of articles or to impart other properties to the composition. The composition can be contacted with a surface to be cleaned in a number of ways and under a number of conditions depending on the manufacturing or processing variables present.

### FIELD OF THE INVENTION

This invention relates to a composition and method for removing soils, fluxes, polymers or other contaminates from electronic and semiconductor devices.

### BACKGROUND

In the manufacturing processes for electronic devices, there are solder fluxes, polymers, oils, greases, soils, and other contaminates that are either deliberately added for ease of manufacture, or are introduced undesirably to the part. It is required that these contaminates be removed before certain steps or after completion of the product. Failure to completely remove these contaminates from products can lead to a wide range of failures, from being aesthetically unpleasing, to a catastrophic product failure that may result in the loss of life.

### BRIEF SUMMARY OF THE INVENTION

According to the present invention, a composition is provided which is effective for removing solder flux, polymeric residue ionic residues and other undesirable contaminates either as a concentrated material or diluted with water. The composition is effective to remove, in conjunction with a rinsing and/or drying step, undesirable contaminates from an electronic device, including but not limited to, solder flux and polymers. The term “electronic devices” includes parts such as printed circuit boards, ceramic electronic devices, silicon wafers and the like. The composition comprises butylpyrrolidone and an alkali and has a pH of at least about 7.1 and a pKa of less than 12. The butylpyrrolidone is chosen from butylpyrrolidones: n-butylpyrrolidone, sec-butylpyrrolidone, 2-methyl-1 propylpyrrilidone and tertiary-butylpyrrolidone, and mixtures thereof. It is to be distinctly understood that any particular butylpyrrolidone may not be completely pure and may have other pyrrolidones mixed with it. Such ingredients are considered to be mixtures within the scope of the claims. The butylpyrrolidone is present in the inventive composition in an amount between about 0.1 and about 100 percent. The alkali used in the composition is an amine or hydroxide in an amount sufficient to render the pH between about 7.1 and about 14.

Water may be present in the composition in an amount of about 0.01 to about 99.9 percent.

Optionally, the composition could include a secondary solvent.

The present invention also contemplates a method of removing solder flux and/or polymer and other undesirable contaminates by contacting a substrate containing the solder flux and/or polymer with the composition of the invention. In this context, “substrate” is defined as any part or manufactured electronic device such as a printed circuit board, ceramic electronic part or silicon wafer that is contaminated with solder flux and/or polymer or other undesirable contaminates.

Optionally a surfactant may be added to the concentrated composition to assist in cleaning efficacy. Optionally corrosion inhibitors, buffering agents, chelating agents and/or sequestrants may be added as would be known by one skilled in the art. The concentrated composition may be used neat (at 100 percent) or diluted with water to result in a concentration of the composition as discussed above. The use of the dilute or the concentrated cleaning agent will allow for the use of the cleaning agent in multiple styles of cleaning machines and cleaning processes. When diluted the concentration of the composition is an amount effective to dissolve or remove and clean solder flux and/or polymer and other undesirable contaminates from the electronic device. It is to be noted that all concentrations in the specification and claims of this application are in weight percent unless noted otherwise.

### DETAILED DESCRIPTION OF THE INVENTION

In accordance with the invention, novel cleaning compositions are formulated comprising butylpyrrolidone and one or more alkaline agents that render the pH of the concentrated cleaning composition greater than about 7.1 and a pKa less than 12. Optionally, the composition contains one or more additional solvents, water, surface active agents, corrosion inhibitors, chelation or sequestering agents, or pH buffering agents, as known by those skilled in the art.

The use of the dilute or the concentrated cleaning agent will allow for the use of the cleaning agent in multiple styles of cleaning machines and cleaning processes.

As discussed above, the invention contemplates a concentrated liquid cleaning composition which comprises butylpyrrolidone and a sufficient amount of an alkali to result in a pH of at least about 7.1 and a pKa of less than 12. The composition may be diluted with water to a concentration of 0.1 to 99 percent. In preferred embodiments, the composition is not diluted, meaning that the cleaning agent has a concentration of 100 percent or is diluted with water to a 5 to 30 percent cleaning agent concentration.

In another embodiment, the composition may contain at least one additional secondary solvent that imparts different solubility parameters for different soils, solder fluxes, polymers, or other contaminates. The optional secondary solvent could be present in an amount of from about 0.1 to about 99.9 percent. One optional secondary solvent is a glycol ether of the formula R₁—O—(C_{×}H₂ₓO)ₙ—H, wherein:
R₁ is an alkyl group having 1 to 8 carbon atoms,
n is integer between 1 and 10, and
x is 2 or 3.

The glycol ether is one or more chosen from propylene glycol methyl ether, dipropylene glycol methyl ether, tripropylene glycol methyl ether, propylene glycol methyl ether acetate, dipropylene glycol methyl ether acetate, propylene glycol n-propyl ether, dipropylene glycol propyl ether, propylene glycol butyl ether, dipropylene glycol butyl ether, tripropylene glycol butyl ether, poly propylene glycol butyl ether, propylene glycol phenyl ether, propylene glycol diacetate, polypropylene glycol butyl ether, diethylene glycol ethyl ether, diethylene glycol methyl ether, diethylene glycol butyl ether, diethylene glycol hexyl ether, diethylene glycol butyl ether acetate, ethylene glycol propyl ether, ethylene glycol n-butyl ether, ethylene glycol hexyl ether, ethylene glycol n-butyl ether acetate, triethylene glycol methyl ether, triethylene glycol ethyl ether, triethylene glycol butyl ether, polyethylene glycol butyl ether, ethylene glycol phenyl ether, polyethylene glycol ethyl ether, and mixtures thereof.

Other optional secondary solvents are oxygenated solvents such as alcohols, polyols and sulfoxides which impart polar solvency and also aid as coupling agents. One optional secondary solvent is of the formula: CₓH_{y}O_{z}Sₙ, wherein:
x is an integer between 2 and 8,
y is an integer between 5 and 18,
z is 1 to 5, and
n is 0 or 1.

Optional solvents of this form are ethanol, n-propanol, isopropanol, n-butanol, isobutanol, t-butanol, n-pentanol, isopentanol, tetrahydrofurfuryl alcohol, hexanol, cyclohexanol, ethylhexanol, ethylene glycol, propylene glycol, glycerol, butanediol, butanetriol, pentanediol, pentanetriol and dimethylsulfoxide.

The alkali is an amine or a hydroxide and is present in an amount sufficient to render the pH between about 7.1 and about 14. Additionally, the pKa of the material is less than 12.0. Preferably, the amine is an alkanolamine present in an amount of between about 0.1 and 50 percent and or a hydroxide present in an amount between 0.01 and 20 percent. More preferably, the alkali agent is present in an amount to render the pH between about 8 and about 13.

The alkanolamine is chosen from monoethanolamines, diethanolamines, triethanolamines, aminomethylpropanol, methylethanolamine, methyldiethanolamine, dimethylethanolamine, diglycolamine, methylethanolamine, monomethylethylethanolamine, dimethylaminopropylamine, aminopropyldiethanolamine, isopropylhydroxylamine, dimethylamino methyl propanol, aminoethylpropanediol, aminoethylpropanediol, dimethyl aminomethylpropanol tris(hydroxymethyl) aminomethane, aminobutanol, diglycolamine, dimethylaminopropanol, ethylaminoethanol, butylaminoethanol, dibutylaminoethanol, butyldiethanolamine, aminomethylbutanol, hydroxyethylpiperazine ethanesulfonic acid, morpholino propanesulfonic acid, bis(hydroxyethyl) aminotris (hydroxymethyl) methane, propanolamine, isopropanolamine, dipropanolamine, diisopropanolamine and combinations thereof. The alkali hydroxide is chosen from tetramethyl ammonium hydroxide, tetrabutyl ammonium hydroxide, tetrapropyl ammonium hydroxide, sodium hydroxide, or potassium hydroxide.

One or more surface active agents preferably are added to improve cleaning, or processing. The surface active agent could be an anionic surfactant, a cationic surfactant, or a nonionic surfactant. The surfactant is preferably present in an amount of from about 0.1 to about 10 percent.

The anionic surfactant is chosen from sulfate surfactants, alkyl sulfate surfactants, sulfonate surfactants, phosphate surfactants, phosphonate surfactants, and carboxylate surfactants.

The cationic surfactant is chosen from primary, secondary, tertiary, or quaternary amines and their salts.

The nonionic surfactant is chosen from polyoxyethylene glycol alkyl ethers, polyoxypropylene glycol alkyl ethers, acetylenic diols, glucoside alkyl ethers, polyoxyethylene glycol octylphenyl ethers, polyoxyethylene glycol alkylphenol ethers, block polymers of ethylene oxide and propylene oxide and fluorinated surfactants.

One or more corrosion inhibitors may be added to the composition to improve compatibility with either the equipment used to apply or remove the cleaning agent or with the electronic product that is undergoing the cleaning process. Preferred corrosion inhibitors are chosen from phosphonates, silicates, molybdates, tungstenates, carbonates, hydroxides, carboxylic acids, benzotriazoles, tolyl triazoles, and mixtures thereof. The corrosion inhibitor is present in an amount of from about 0.001 to about 10 percent.

One or more buffering agents may be added to provide pH control to maintain the pH at between about 7.1 and about 14. Preferred buffering agents are chosen from mono, di and tri-carboxylic acids, amines, inorganic acids, and mixtures thereof. The preferred buffering agent is one or more of monocarboxylic acids, dicarboxylic acids, phosphoric acid, phosphonic acids, sulfuric acid, boric acid, and their salts.

At least one chelating or sequestering agent may be added to the composition. Preferred chelation or sequestering agents are ethylenediaminetetraacetic acid (EDTA) or its salts and ethylenediamine-N,N′-disuccinic acid or its salts, phosphonic acid or its salts and mixtures thereof.

Optionally, a foaming modifying agent of a type well known in the art may be included.

In another aspect of the invention, a method is provided which comprises contacting a product as described above with the composition of the instant invention for a time sufficient to remove the solder flux or other contaminant in a manner known to those skilled in the art of cleaning. The wash is followed by a rinse stage to remove the composition from the part followed by a dry stage. Wash and rinse can be accomplished by means of spraying, spray under immersion, agitation, ultrasonics, dipping, tumbling, wiping or immersion.

Preferred embodiments of the composition and method of the present invention are described in detail in the following examples which should not be construed to limit the scope of the present invention.

### Comparative Example 1

A cleaning agent was formulated with 100 percent n-butylpyrrolidone to test removal of various commercial fluxes encountered in industry. The solution was heated to 60 degrees C. in a beaker agitated with a stirbar at low speed. Test circuit boards with flux were immersed in the solution for 5, 10 and 15 minutes and then were rinsed for 2 minutes with deionized water and were dried with hot air. The boards were then inspected. Below are the results of that test in percent clean:

| Flux Name | 5 Min Score | 10 Min Score | 15 Min Score |
|---|---|---|---|
| Alpha OM-338PT | 70 | 75 | 70 |
| Indium 8.9HF1 | 60 | 60 | 80 |
| Indium 8.9HF1-P | 70 | 70 | 70 |
| Koki S3X70-M407-3 | 60 | 70 | 85 |
| Koki S3X48-M500 | 70 | 75 | 80 |
| Senju-S70G-HF | 85 | 75 | 85 |
| Senju M705-GRN360 | 85 | 90 | 90 |

### Example 1

A solution was formulated with 95 percent N-butyl pyrollidone and 5 percent of diglycolamine (pH=11.6, pKa=9.45) was heated to 60 C in a beaker agitated with a stirbar at low speed. Test circuit boards with flux were immersed in the solution for 5, 10 and 15 minutes and then were rinsed for 2 minutes with deionized water and were dried with hot air. The boards were then inspected. Below are the results of that test in percent clean with comparative score in parentheses:

| Flux Name | 5 Min Score | 10 Min Score | 15 Min Score |
|---|---|---|---|
| Alpha OM-338PT | 98 (70) | 100 (75) | 100 (70) |
| Indium 8.9HF1 | 75 (60) | 90 (60) | 98 (80) |
| Indium 8.9HF1-P | 85 (70) | 85 (70) | 95 (70) |
| Koki S3X70-M407-3 | 85 (60) | 99 (70) | 100 (85) |
| Koki S3X48-M500 | 85 (70) | 99 (75) | 100 (80) |
| Senju-S70G-HF | 95 (85) | 90 (75) | 90 (85) |
| Senju M705-GRN360 | 98 (85) | 100 (90) | 100 (90) |

In all 21 tests under the same conditions the addition of the alkaline material diglycolamine improved the cleaning of the neat N-butylpyrollidone.

### Example 2

A solution was formulated with 85 percent N-butyl pyrollidone and 5 percent of diglycolamine (pH=11.6, pKa=9.45) and 10 percent dipropylene glycol n-butyl ether. The mixture was heated to 60 degrees C. in a beaker agitated with a stirbar at low speed. Test circuit boards with flux were immersed in the solution for 5, 10 and 15 minutes and then were rinsed for 2 minutes with deionized water and were dried with hot air. The boards were then inspected. Below are the results of that test in percent clean with comparative score in parentheses:

| Flux Name | 5 Min Score | 10 Min Score | 15 Min Score |
|---|---|---|---|
| Alpha OM-338PT | 96 (70) | 90 (75) | 98 (70) |
| Indium 8.9HF1 | 80 (60) | 85 (60) | 95 (80) |
| Indium 8.9HF1-P | 85 (70) | 85 (70) | 85 (70) |
| Koki S3X70-M407-3 | 85 (60) | 85 (70) | 90 (85) |
| Koki S3X48-M500 | 85 (70) | 80 (75) | 85 (80) |
| Senju-S70G-HF | 85 (85) | 90 (75) | 85 (85) |
| Senju M705-GRN360 | 100 (85) | 100 (90) | 100 (90) |

In 19 of 21 tests under the same conditions the addition of the alkaline material diglycolamine and the addition of the glycol ether dipropylene glycol n-butyl ether improved the cleaning of the neat N-butylpyrollidone.

### Comparative Example 2

A cleaning agent was formulated with 100 percent n-butylpyrrolidone as in Comparative Example 1. This test was to evaluate the ability to remove the same commercial fluxes using an aqueous process where the concentrated solution is diluted with water and sprayed onto the part. The test solution was added to water to make a 15 percent solution. The 15 percent solution had a pH of 4.6. The 15 percent cleaning solution was placed in a commercial batch cleaning machine (Aqueous Technologies SMT800-LD) and cleaned by spraying in air on the boards. The cleaning solution was heated to 60 degrees C. in the machine holding tank and was sprayed on the test boards at the same temperature. The test boards with flux were cleaned in the machine for 15 and 30 minutes and then were rinsed for 5 minutes with deionized water and were dried with hot air. The boards were then inspected. Below are the results of that test in percent clean:

| Flux Name | 15 Min Score | 30 Min Score |
|---|---|---|
| Alpha OM-338PT | 25 | 30 |
| Indium 8.9HF1 | 5 | 20 |
| Indium 8.9HF1-P | 10 | 50 |
| Koki S3X70-M407-3 | 20 | 25 |
| Koki S3X48-M500 | 25 | 40 |
| Senju-S70G-HF | 15 | 30 |
| Senju M705-GRN360 | 20 | 40 |

### Example 3

The cleaning agent from Example 1 was formulated with 95 percent n-butylpyrrolidone and 5 percent diglycolamine. The solution was then added to water to make a 15 percent solution. The 15 percent solution had a pH of 10.7 and pKa of 9.45. The 15 percent cleaning solution was placed in a commercial batch cleaning machine (Aqueous Technologies SMT800-LD) and cleaned by spraying in air on the boards. The cleaning solution was heated to 60 degrees C. in the machine holding tank and was sprayed on the test boards at the same temperature. The test boards with flux were cleaned in the machine for 15 and 30 minutes and then were rinsed for 5 minutes with deionized water and were dried with hot air. The boards were then inspected. Below are the results of that test in percent clean with comparative score in parentheses:

| Flux Name | 15 Min Score | 30 Min Score |
|---|---|---|
| Alpha OM-338PT | 40 (25) | 60 (30) |
| Indium 8.9HF1 | 25 (5) | 30 (20) |
| Indium 8.9HF1-P | 40 (10) | 40 (50) |
| Koki S3X70-M407-3 | 30 (20) | 30 (25) |
| Koki S3X48-M500 | 50 (25) | 40 (40) |
| Senju-S70G-HF | 50 (15) | 40 (30) |
| Senju M705-GRN360 | 40 (20) | 40 (40) |

In 13 of 14 tests under the same conditions the addition of the alkaline material diglycolamine and was equal to or improved the cleaning of the neat N-butylpyrollidone.

### Example 4

The cleaning agent from Example 2 was formulated with 85 percent n-butylpyrrolidone and 5 percent diglycolamine and 10 percent dipropylene glycol n-butyl ether. The solution was then added to water to make a 15 percent solution. The 15 percent solution had a pH of 10.7 and pKa of 9.45. The 15 percent cleaning solution was placed in a commercial batch cleaning machine (Aqueous Technologies SMT800-LD) and cleaned by spraying in air on the boards. The cleaning solution was heated to 60 degrees C. in the machine holding tank and was sprayed on the test boards at the same temperature. The test boards with flux were cleaned in the machine for 15 and 30 minutes and then were rinsed for 5 minutes with deionized water and were dried with hot air. The boards were then inspected. Below are the results of that test in percent clean with comparative score in parenthesis:

| Flux Name | 15 Min Score | 30 Min Score |
|---|---|---|
| Alpha OM-338PT | 85 (25) | 95 (30) |
| Indium 8.9HF1 | 75 (5) | 70 (20) |
| Indium 8.9HF1-P | 70 (10) | 80 (50) |
| Koki S3X70-M407-3 | 30 (20) | 40 (25) |
| Koki S3X48-M500 | 60 (25) | 50 (40) |
| Senju-S70G-HF | 60 (15) | 80 (30) |
| Senju M705-GRN360 | 40 (20) | 60 (40) |

In all 14 tests under the same conditions the addition of the alkaline material diglycolamine and the addition of the glycol ether dipropylene glycol n-butyl ether improved the cleaning of the neat N-butylpyrollidone.

### Comparative Example 3

A cleaning agent was formulated with 100 percent n-butylpyrrolidone in a test to evaluate the cleaning various polymeric resist materials off of silicon wafers. Two commercial and one proprietary polymers classified as “dry film” photoresist were selected for the example. The solution was heated to 75 degrees C. in a beaker agitated with a stirbar at low speed. Test wafers with polymeric photoresist immersed in the solution for 90 minutes and then were rinsed for 2 minutes with deionized water and were dried with hot air. The boards were then inspected. Below are the results of that test in percent clean:

| Photoresist Name | Percent Clean Score |
|---|---|
| DuPont WBR 2015 | 85 |
| Proprietary Resist | 80 |
| TOK MP112 | 55 |

### Example 5

A cleaning agent was formulated with 75 percent n-butylpyrrolidone, 18.75 percent water and 6.25 percent Tetramethylammonium hydroxide were formulated in a test to evaluate the cleaning various polymeric resist materials off of silicon wafers. The pH of the solution was 13.1 and the pKa was 9.8. The same two commercial and one proprietary polymers classified as “dry film” photoresist were selected for the example. The solution was heated to 75 degrees C. in a beaker agitated with a stirbar at low speed. Test wafers with polymeric photoresist immersed in the solution for 90 minutes and then were rinsed for 2 minutes with deionized water and were dried with hot air. The boards were then inspected. Below are the results of that test in percent clean with comparative score in parenthesis:

| Photoresist Name | Percent Clean Score |
|---|---|
| DuPont WBR 2015 | 100 (85) |
| Proprietary Resist | 85 (80) |
| TOK MP112 | 80 (55) |

The addition of the alkaline material improved the cleaning of the wafer over the neat solvent.

### Example 6

A cleaning agent was formulated with 50 percent n-butylpyrrolidone, 37.5 percent water and 12.5 percent tetramethylammonium hydroxide were formulated in a test to evaluate the cleaning various polymeric resist materials off of silicon wafers. The pH of the solution was 13.6 and the pKa was 9.8. The same two commercial and one proprietary polymers classified as “dry film” photoresist were selected for the example. The solution was heated to 75 degrees C. in a beaker agitated with a stirbar at low speed. Test wafers with polymeric photoresist immersed in the solution for 90 minutes and then were rinsed for 2 minutes with deionized water and were dried with hot air. The boards were then inspected. Below are the results of that test in percent clean with comparative score in parenthesis:

| Photoresist Name | Percent Clean Score |
|---|---|
| DuPont WBR 2015 | 100 (85) |
| Proprietary Resist | 95 (80) |
| TOK MP112 | 95 (55) |

The addition of an increased level of alkalinity and reduced level of butylpyrrolidone actually increased the cleaning.

### Example 7

A cleaning agent was formulated with 34 percent n-butylpyrrolidone, 33 percent dimethylsulfoxide, 24.75 percent water and 8.25 percent tetramethylammonium hydroxide were formulated in a test to evaluate the cleaning various polymeric resist materials off of silicon wafers. The pH of the solution was 13.6 and the pKa was 9.8. The same two commercial and one proprietary polymers classified as “dry film” photoresist were selected for the example. The solution was heated to 75 degrees C. in a beaker agitated with a stirbar at low speed. Test wafers with polymeric photoresist immersed in the solution for 90 minutes and then were rinsed for 2 minutes with deionized water and were dried with hot air. The boards were then inspected. Below are the results of that test in percent clean with comparative score in parenthesis:

| Photoresist Name | Percent Clean Score |
|---|---|
| DuPont WBR 2015 | 100 (85) |
| Proprietary Resist | 100 (80) |
| TOK MP112 | 100 (55) |

The addition of an increased level of alkalinity coupled with a polar solvent resulted in completely clean wafers demonstrating the value of a formulated product versus a single solvent.

### Example 8

A cleaning agent was formulated with 100 percent n-butylpyrrolidone to evaluate the cleaning of a cured generic novolak type polymeric adhesive. The solution was heated to 75 degrees C. in a beaker agitated with a stirbar at low speed. Test substrates with polymeric adhesive immersed in the solution for 90 minutes and then were rinsed for 2 minutes with deionized water and were dried with hot air. The metal substrates were then inspected. Below are the results of that test in percent clean:

| Adhesive Name | Percent Clean Score |
|---|---|
| Polymeric Adhesive 1 | 75 |

### Example 9

A cleaning agent was formulated with 90 percent n-butylpyrrolidone, 10 percent diglycolamine (pH=11.6, pKa=9.45) to evaluate the cleaning of cured generic novolak type polymeric adhesive. The solution was heated to 75 degrees C. in a beaker agitated with a stirbar at low speed. Test substrates with polymeric adhesive immersed in the solution for 90 minutes and then were rinsed for 2 minutes with deionized water and were dried with hot air. The metal substrates were then inspected. Below are the results of that test in percent clean:

| Adhesive Name | Percent Clean Score |
|---|---|
| Polymeric Adhesive 1 | 85 |

### Example 10

A cleaning agent was formulated with 70 percent n-butylpyrrolidone, 10 percent diglycolamine (pH=11.6, pKa=9.45), 20 percent propylene carbonate to evaluate the cleaning of cured generic novolak type polymeric adhesive. The solution was heated to 75 degrees C. in a beaker agitated with a stirbar at low speed. Test substrates with polymeric adhesive immersed in the solution for 90 minutes and then were rinsed for 2 minutes with deionized water and were dried with hot air. The metal substrates were then inspected. Below are the results of that test in percent clean with comparative score in parenthesis:

| Adhesive Name | Percent Clean Score |
|---|---|
| Polymeric Adhesive 1 | 100 (85) |

The addition of an increased level of alkalinity coupled with a solvent resulted in completely clean metal substrates demonstrating the value of a formulated product versus a single solvent.

What is claimed is:

1. A composition effective for removing contaminants from electronic parts or assemblies during manufacture comprising at least one butylpyrrolidone; and an alkali, and has a pH of at least about 7.1 and a pKa less than 12.

2. The composition of claim 1 further comprising water.

3. The composition of claim 2 wherein said water is present in an amount of from about 0.1 to about 99.9 percent.

4. The composition of claim 1 further comprising a secondary solvent.

5. The composition of claim 1, wherein said secondary solvent is present in an amount from about 0.1 percent to about 99.9 percent.

6. The composition of claim 4, wherein the secondary solvent is a glycol ether of the formula R₁—O—(CₓH₂ₓO)ₙ—H, wherein:
R₁ is an alkyl group having 1 to 8 carbon atoms,
n is an integer between 1 and 10, and
x is 2 or 3.

7. The composition of claim 6, wherein the secondary solvent is chosen from propylene glycol methyl ether, dipropylene glycol methyl ether, tripropylene glycol methyl ether, propylene glycol methyl ether acetate, dipropylene glycol methyl ether acetate, propylene glycol n-propyl ether, dipropylene glycol propyl ether, propylene glycol butyl ether, dipropylene glycol butyl ether, tripropylene glycol butyl ether, poly propylene glycol butyl ether, propylene glycol phenyl ether, propylene glycol diacetate, polypropylene glycol butyl ether, diethylene glycol ethyl ether, diethylene glycol methyl ether, diethylene glycol butyl ether, diethylene glycol hexyl ether, diethylene glycol butyl ether acetate, ethylene glycol propyl ether, ethylene glycol n-butyl ether, ethylene glycol hexyl ether, ethylene glycol n-butyl ether acetate, triethylene glycol methyl ether, triethylene glycol ethyl ether, triethylene glycol butyl ether, polyethylene glycol butyl ether, ethylene glycol phenyl ether, polyethylene glycol ethyl ether, and mixtures thereof.

8. The composition of claim 4, wherein the secondary solvent is an alcohol or polyol of the formula CₓH_{y}O_{z}Sₙ, wherein:
x is an integer between 2 and 8,
y is an integer between 5 and 18, and
z is an integer between 1 and 5
n is 0 or 1.

9. The composition of claim 8, wherein the secondary solvent is chosen from ethanol, n-propanol, isopropanol, n-butanol, isobutanol, t-butanol, n-pentanol, isopentanol, tetrahydrofurfuryl alcohol, hexanol, cyclohexanol, ethylhexanol, ethylene glycol, propylene glycol, glycerol, butanediol, butanetriol pentanediol, pentanetriol and dimethyl sulfoxide, and mixtures thereof.

10. The composition of claim 1, wherein the alkali is an amine or a hydroxide in an amount sufficient to render the pH between about 7.1 and about 14 and a pKa less than 12.

11. The composition of claim 10, wherein the alkali is present in an amount between about 0.1 and about 50 percent.

12. The composition of claim 10, wherein the alkali is an amine is present in an amount to render the pH between about 8 to about 13.

13. The composition of claim 10, wherein the amine is an alkanolamine.

14. The composition of claim 13, wherein the alkanolamine is chosen from monoethanolamines, diethanolamines, triethanolamines, aminomethylpropanol, methylethanolamine, methyldiethanolamine, dimethylethanolamine, diglycolamine, methylethanolamine, monomethylethylethanolamine, dimethylaminopropylamine, aminopropyldiethanolamine, isopropylhydroxylamine, dimethylamino methyl propanol, aminoethylpropanediol, aminoethylpropanediol, dimethyl aminomethylpropanol tris(hydroxymethyl) aminomethane, aminobutanol, diglycolamine, dimethylaminopropanol, ethylaminoethanol, butylaminoethanol, dibutylaminoethanol, butyldiethanolamine, aminomethylbutanol, hydroxyethylpiperazine ethanesulfonic acid, morpholino propanesulfonic acid, bis(hydroxyethyl) aminotris (hydroxymethyl) methane, propanolamine, isopropanolamine, dipropanolamine, diisopropanolamine and combinations thereof. The alkali hydroxide is chosen from tetramethyl ammonium, tetrabutyl ammonium, tetrapropyl ammonium, sodium or potassium hydroxide.

15. The composition of claim 10 wherein the alkali is tetrapropyl ammonium hydroxide or potassium hydroxide.

16. A composition of claim 1, wherein said ester of butylpyrrolidone is present at a concentration of about 0.1 to about 100 percent.

17. The composition of claim 16, wherein the butylpyrrolidone is N-butylpyrrolidone

18. The composition of claim 1, further comprising a surfactant.

19. The composition of claim 18, wherein said surfactant is present in an amount of from about 0.1 to about 10 percent.

20. The composition of claim 19, wherein said surfactant is chosen from anionic surfactants, cationic surfactants, nonionic surfactants, and mixtures thereof.

21. The composition of claim 20, wherein:
a. said anionic surfactant is chosen from sulfate surfactants, alkyl sulfate surfactants, sulfonate surfactants, phosphate surfactants, phosphonate surfactants, and carboxylate surfactants;
b. said cationic surfactant is chosen from primary, secondary, tertiary, or quaternary amines and their salts; and
c. said nonionic surfactant is chosen from polyoxyethylene glycol alkyl ethers, polyoxypropylene glycol alkyl ethers, acetylenic diols, glucoside alkyl ethers, polyoxyethylene glycol octylphenyl ethers, polyoxyethylene glycol alkylphenol ethers, and block polymers of ethylene oxide and propylene oxide and fluorinated surfactants.

22. The composition of claim 1, further comprising a corrosion inhibitor.

23. The composition of claim 22, wherein said corrosion inhibitor is chosen from phosphonates, silicates, molybdates, tungstenates, carbonates, hydroxides, carboxylic acids, azoles, and mixtures thereof.

24. The composition of claim 23 wherein said corrosion inhibitor is chosen from sodium silicate, sodium metasilicate, potassium silicate, tetramethylammonium silicate, benzotriazole and tolyltriazole

25. The composition of claim 22, wherein said corrosion inhibitor is present in an amount of about 0.001 to about 10 percent.

26. The composition of claim 1, further comprising a buffering agent.

27. The composition of claim 26, wherein said buffering agent is chosen from carboxylic acids, and inorganic acids, and mixtures thereof.

28. The composition of claim 27, wherein said buffering agent is one or more of, 5 to 18 carbon monocarboxylic acids, 5 to 18 carbon dicarboxylic acids, phosphoric acid, phosphonic acid, sulfuric acid, boric acid, and their salts.

29. The composition of claim 26, wherein said buffering agent is present at a concentration effective to keep the pH at from 7.1 to 14 and pKa less than 12.

30. The composition of claim 1, further including at least one chelating agent.

31. The composition of claim 31, wherein said chelating agent is selected from the group consisting of ethylenediaminetetraacetic acid or its salts and ethylenediamine-N,N=-disuccinic acid or its salts, phosphonic acid or its salts and mixtures thereof.

32. The composition of claim 1, further including a foaming modifying agent.

33. The composition of claim 1, wherein said contaminant is solder flux.

34. The composition of claim 1, wherein said contaminant is a polymeric photoresist

35. The composition of claim 1, wherein said contaminant is an adhesive.

36. The composition of claim 1 wherein said contaminant is ionic in nature and is capable of causing stray unwanted electrical current between two points on the electronic component

37. A method of removing a contaminant from a substrate comprising contacting said substrate with the composition of claim 1 at a temperature and a contact time sufficient to remove said solder flux.

38. A method according to claim 37, further comprising a cleaning step, and wherein the cleaning step is at a temperature between 20 degrees C. and the boiling point and a time between 1 to 1000 seconds and at a cleaning pressure of −0.3 to 2 atmospheres.

39. A method according to claim 38, wherein said cleaning step comprises a washing stage followed by a rinsing stage and a drying stage.

40. A method according to claim 39, where the rinsing stage is conducted with a rinse fluid which comprises said cleaning agent, water, deionized water or a fluorinated containing solvent.

41. A method of cleaning contaminants from electronic parts or assemblies during manufacture comprising contacting said parts or assemblies with the composition of claim 2 for a time sufficient to remove said contaminants.
